(19) United States
(12) Patent Application Publication
(10) Pub. No.: US 2018/0026626 A1
(43) Pub. Date: Jan. 25, 2018

(54) ADAPTIVE GATE DRIVER

(71) Applicant: Infineon Technologies Austria AG, Villach (AT)

(72) Inventors: Yong Siang Teo, Singapore (SG); Xiaowu Gong, Singapore (SG)

(21) Appl. No.: 15/218,829

(22) Filed: Jul. 25, 2016

(51) Int. Cl. H03K 17/16; H03K 17/687; H03K 17/10

(52) U.S. Cl. CPC H03K 17/163; H03K 17/102; H03K 17/6871

(57) ABSTRACT

A device driver is described that includes an output stage and one or more control components. The output stage is configured to produce a gate driver output for driving a gate terminal of a semiconductor device, the output stage comprising a variable driving capability. The one or more control components are configured to obtain an indication of a rise time of the gate driver output during an initial switching cycle of the semiconductor device, and prior to a subsequent switching cycle of the semiconductor device, adjust, based on the indication of the rise time, a driving capability of the device driver from a first level to a second level. The one or more control components are further configured to cause the output stage to output the gate driver output at the second level of driving capability during the subsequent switching cycle of the semiconductor device.

### TECHNICAL FIELD

This disclosure relates to gate drivers for driving semiconductor devices.

### BACKGROUND

The output power demands of a Switching Mode Power Supply (SMPS) can range widely depending on the load. For example, the output power of a SNIPS could range from ten watts to sixty watts across a variety of home appliance products that use different power metal-oxide-semiconductor field-effect-transistors (MOSFETs) having different on-resistances (R_{DSon}) or having different breakdown voltage ratings. For economies of scale (e.g., cost, productivity, and quality control), some manufacturers may rely on a single controller design to drive a load, regardless of the size of the load or application. However, using a universal controller design for driving different loads has some drawbacks.

For example, when the same AC-DC pulse-width-modulation (PWM) controller is used to drive loads (e.g., power MOSFETs) of varying R_{DSon} or breakdown voltage ratings, the rise time for a smaller load might be very fast, resulting in increased radiated electromagnetic interference (EMI). Conversely, the rising time for a larger load may be too slow when being driven by a universal controller resulting in an increase in switching losses. An increase in radiated EMI may result in an increase in the complexity of the overall system design to compensate for the increased EMI radiation. An increase in switching losses may lower the whole system efficiency.

Rather than rely on a single universal controller design, some controller manufacturers may provide a variety of controller designs that are each customized according to a particular loading or a particular application. Unfortunately, providing multiple controller designs may eliminate the benefits that universal controller designs give to economies of scale. Alternatively, some controller manufacturers may recommend or provide a way for end customers to trim the driver capability of a controller through backend trimming. However, backend trimming of the driver capability of a controller may not reduce overall system complexity, rather, the burden of an increase in complexity may simply shift from the controller manufacturer to the end customer that now must account for variable driving capability. And still other controller manufacturers or customers may include a gate resistor of varying size, depending on the intended loading conditions, after the drive stage and before the gate of the semiconductor device so as to statically adjust the gate rise time. The introduction of a gate resistor may increase the material and manufacturing cost. In addition, in some solutions, the semiconductor device and controller are integrated into a single package, and therefore, rendering use of a gate resistor impossible.

### SUMMARY

In general, circuits and techniques are described for enabling a system (e.g., a device driver of a controller of a SNIPS) to dynamically tune its driving capability according to the loading at the gate output. The system may undergo variations in rise time of a gate driver output (e.g., due to variations in power MOSFETs, different R_{DSon} values, different breakdown voltage ratings, or other variations in load characteristics at the output stage of the system) and dynamically adjust its driving capability accordingly, so as to limit mitigate increases in radiated EMI or switching losses that might otherwise occur.

Rather than provide a static driving capability that is sufficient to support a wide range of load conditions, an example driver may vary its driving capability based on the rise time of the gate driver output. For example, when the size of the load is small, the gate rise time may tend to be faster, and when the size of the load is large, the gate rise time may typically be slower. The driver may monitor an indication of the rise time of the gate driver output to determine whether the rise time is sufficiently slow or sufficiently fast (e.g., for switching-on a semiconductor device) and if not, the driver may dynamically adjust the strength of the gate driver output to vary the rise time accordingly.

In one example, the disclosure is directed to a device driver that includes one or more control components and an output stage configured to produce a gate driver output for driving a gate terminal of a semiconductor device, the output stage comprising a variable driving capability. The one or more control components are configured to obtain art indication of a rise time of the gate driver output during an initial switching cycle of the semiconductor device, and prior to a subsequent switching cycle of the semiconductor device, adjust, based on the indication of the rise time, a driving capability of the device driver from a first level to a second level. The one or more control components are further configured to cause the output stage to output the gate driver output at the second level of driving capability during the subsequent switching cycle of the semiconductor device.

In another example, the disclosure is directed to a system that includes means for obtaining an indication of a rise time of a gate driver output during an initial switching cycle of a semiconductor device. The system further includes, prior to a subsequent switching cycle of the semiconductor device, means for adjusting, based on the indication of the rise time, a driving capability of the system from a first level to a second level, and means for outputting at the second level of driving capability, the gate driver output during the subsequent switching cycle of the semiconductor device.

In another example, the disclosure is directed to a method that includes obtaining, by a device driver, an indication of a rise time of a gate driver output during an initial switching cycle of a semiconductor device, and prior to a subsequent switching cycle of the semiconductor device, adjusting, by the device driver, based on the indication of the rise time, a driving capability of the device driver from a first level to a second level. The method further includes outputting, by the device driver, at the second level of driving capability, the gate driver output during the subsequent switching cycle of the semiconductor device.

The details of one or more examples are set forth in the accompanying drawings and the description below. Other features, objects, and advantages of the disclosure will be apparent from the description and drawings, and from the claims.

### BRIEF DESCRIPTION OF DRAWINGS

FIG. 1 is a block diagram illustrating an example system having dynamic drive capability for controlling a semiconductor device, in accordance with one or more aspects of the present disclosure.

FIG. 2 is a flow diagram illustrating operations performed by an example system having dynamic drive capability for controlling a semiconductor device, in accordance with one or more aspects of the present disclosure.

FIG. 3 is a block diagram illustrating an example semiconductor device driver having dynamic drive capability for driving a semiconductor device, in accordance with one or more aspects of the present disclosure.

FIG. 4 is a flow diagram illustrating operations performed by the example semiconductor device driver shown in FIG. 3.

FIG. 5 is a block diagram illustrating another example semiconductor device driver having dynamic drive capability for driving a semiconductor device, in accordance with one or more aspects of the present disclosure.

FIG. 6 is a flow diagram illustrating operations performed by the example semiconductor device driver shown in FIG. 5.

### DETAILED DESCRIPTION

In general, circuits and techniques are described for enabling a system (e.g., a device driver of a controller of a SMPS) to dynamically tune its driving capability according to the precise loading at the gate output. The system may undergo variations in rise time of a gate driver output (e.g., due to variations in power MOSFETs, different R_{DSon} values, different breakdown voltage ratings, or other variations in load characteristics at the output stage of the system) and dynamically adjust its driving capability accordingly. In this way, the system may mitigate increase in radiated EMI or switching losses that would otherwise occur during a device switch-on.

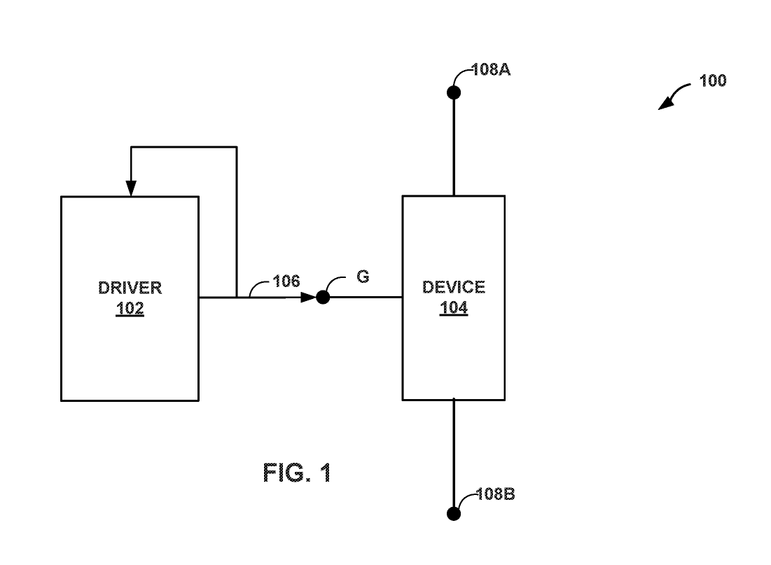

FIG. 1 is a block diagram illustrating an example system having dynamic drive capability for controlling a semiconductor device, in accordance with one or more aspects of the present disclosure. FIG. 1 shows system 100 which includes driver 102 and device 104. The gate drive output of driver 102 is electrically coupled to the gate (G) of device 104 via link 106. System 100 may include additional components than those shown. In some examples, system 100 may be implemented as a single or multiple integrated circuit (IC) packages.

Device 104 represents any conceivable semiconductor device that is configured to receive a gate driver signal from a driver, such as driver 102. For example, device 104 may be a power Metal-Oxide-Semiconductor Field-Effect-Transistor (MOSFET) used in a Switching Mode Power Supply (SMPS), other transistor devices for other applications, or any other type of semiconductor device configured to receive a gate drive signal front a driver.

Device 104 includes three terminals however in other examples, device 104 may include additional terminals. The gate (G) of device 104 is electrically coupled to link 106. Terminals 108A and 108B of device 104 are configured to couple to a voltage source and/or a load. In operations, device 104 may receive, via link 106 and at gate terminal G, a gate driver signal from driver 102 that causes device 104 to change operating states. Depending on the magnitude of the voltage of the gate driver signal at link 106, device 104 may “switch-on” or “switch-oft”. When switched-on, device 104 may conduct a current between terminals 108A and 108B of device 104. When switched-off, device 104 may cease conducting the current, and block a voltage between terminals 108A and 108B of device 104.

Driver 102 provides driver capabilities to system 100 for driving device 104. Driver 102 may be a stand-alone component of system 100 or may be part of a larger system or component of system 100. For example, driver 102 may be a discrete component or in other examples, driver 102 may be part of a controller a modulation controller that controls driver 102, device 104, and other components of system 100).

Driver 102 may comprise any suitable arrangement of hardware, software, firmware, or any combination thereof, to perform the techniques attributed to driver 102 that are described herein. Driver 102 may include any one or more microprocessors, digital signal processors (DSPs), application specific integrated circuits (ASICs), field programmable gate arrays (FPGAs), or any other equivalent integrated or discrete logic circuitry, as well as any combinations of such components. When driver 102 includes software or firmware, driver 102 further includes any necessary hardware for storing and executing the software or firmware, such as one or more memories and one or more processors or processing units. In general, a processing unit may include one or more microprocessors, DSPs, ASICs, FPGAs, or any other equivalent integrated or discrete logic circuitry, as well as any combinations of such components.

Driver 102 is configured to dynamically tune its driving capability according to sensed variations in rise time of the gate driver signal (which are typically attributed to variations in loading associated with device 104). Driver 102 is configured to vary the rise time of the gate driver signal that driver 102 outputs to link 106 so that the rise time fits or is adequate for supporting (e.g., is not too fast or not too slow) the condition of load at its gate drive output (e.g., link 106).

Rather than provide a static driving capability that is sufficient to support a wide range of load conditions, requiring trimming, or relying on gate resistors, driver 102 may vary the driving capability of its gate driver output depending on the load conditions that driver 102 senses via link 106 or the load condition that driver 102 senses or detects in other way. In this way, driver 102 may be used in a universal controller that is configured to drive a wide range of loading requirements without detrimentally effecting rise time, switching losses, or increasing EMI radiation.

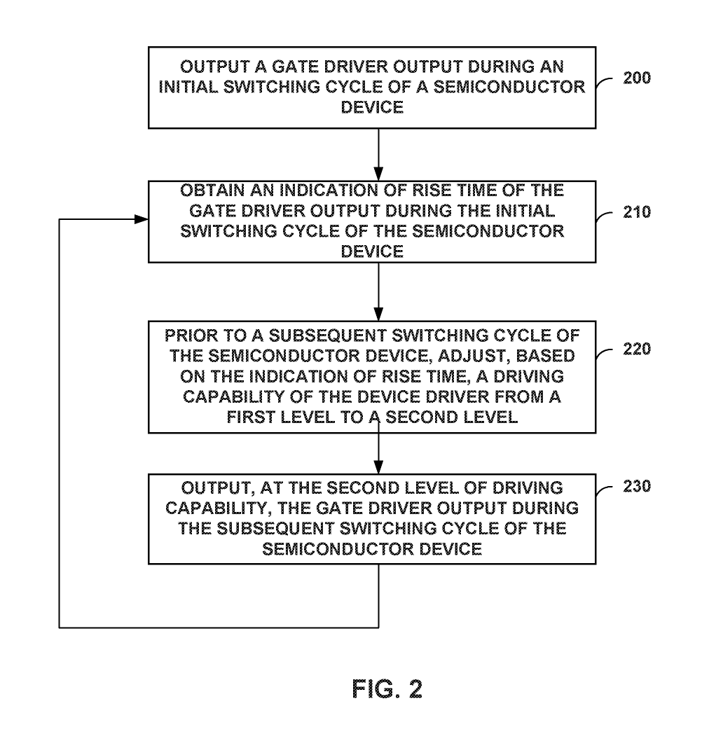

FIG. 2 is a flow diagram illustrating operations performed by an example system having dynamic drive capability for controlling a semiconductor device, in accordance with one or more aspects of the present disclosure. For example, driver 102 of system 100 of FIG. 1 may perform operations 200-230 of FIG. 2 to control device 104 of system 100 of FIG. 1. FIG. 2 is described below in the context of system 100 of FIG. 1.

In operation, driver 102 may output a gate driver output during an initial switching cycle of semiconductor device 104 (200). For example, driver 102 may generate a signal at link 106 to switch-on device 104, for example, by causing the voltage at gate (G) of device 104 to transition from a low voltage (e.g., ground) to a high voltage (e.g., VCC). In some examples, the gate driver output may be a pulse-width-modulation (PWM) signal, pulse-density-modulation (PDM) signal, or any other modulation type signal for switching semiconductor device on and off.

Initially (e.g., after power on of driver 102), driver 102 may drive device 104 with a nominal driving capability which could be a maximum level of driving capability, a minimum level of driving capability, or some other level of driving capability level. For example, driver 102 may drive the gate driver output at link 106 with a greatest amount of charge so that the voltage at the gate (G) of device 104 transitions from a low voltage to a high voltage as fast as possible.

Rather than always drive device 104 at the maximum driving capability, and so as to limit switching losses during switch-on events of device 104, driver 102 may monitor (e.g., continuously, periodically, triggered by an event, during a pre-defined period after power-on, or at some other time(s)) characteristics of the gate driver output at link 106 to infer whether the drive strength or driving capability of the gate driver output, matches the condition of load associated with device 104. Driver 102 may dynamically adjust its driving capability according to the condition of load. Driver 102 may infer the condition of load associated with device 104 by obtaining an indication of rise time associated with the gate driver output and adjust its driving capability based on the indication of rise time.

Driver 102 may obtain the indication of rise time of the gate driver output during the initial switching cycle of semiconductor device 104 (210) to infer the condition of load associated with device 104. For example, driver 102 may measure actual rise time by determining an amount of time that the voltage at link 106 takes to transition from a low voltage to a high voltage either directly (e.g., with a counter that stops counting when the voltage at the gate of device 104 reaches the maximum or pre-defined voltage associated with the gate driver output) or indirectly (e.g., by measuring a voltage level at a capacitor that is allowed to charge during a switch-on of device 104 and comparing the measured voltage to upper and lower voltage thresholds as a way to deduce whether the rise time is too fast or too slow). Or in other examples, driver 102 may obtain an indication of rise time by obtaining a measurement of the voltage at link 106 after a fixed amount of time since the gate driver output began its transition (e.g., since the start of the switching cycle) from low voltage to high voltage and comparing the measured voltage to upper and lower voltage thresholds as a way to deduce whether the rise time is too fast or too slow.

In some examples, driver 102 may obtain an indication of rise time as a discrete quantity of time (e.g., one, ten, or more nanoseconds, seconds, or another discrete time unit). In other examples, driver 102 may obtain an indication of rise time as a relative value that changes in a predictable way based on changes in rise time (e.g., a positive value for slow or a large rise time, a negative value for fast or a small rise time, or a zero value for a neither too fast nor too slow rise time).

Prior to a subsequent switching cycle of semiconductor device 104, driver 102 may adjust, based on the indication of rise time, a driving capability of driver 102 from a first level to a second level (220). For example, when driver 102 senses, based on the indication of rise time, that the rise time at the gate (G) of device 104 is to slow (e.g., longer than a maximum time duration), driver 102 may infer that the size of the load associated with device 104 to be larger than what the current drive capability typically supports, and therefore, increase the driving capability of the gate driver output from a first level to a second level. When driver 102 senses, based on the indication of rise time, that the rise time at the gate (G) of device 104 is too fast (e.g., less than a minimum time duration), driver 102 may infer that the size of the load associated with device 104 to be smaller than what the current drive capability typically supports, and therefore decrease the driving capability of the gate driver output. In some examples, driver 102 may adjust the driving capability of the gate driver output by changing the amount of impedance of the output stage of driver 102. In some examples, driver 102 may adjust the driving capability of the gate driver output by changing the current biasing at the output stage of driver 102.

In some examples, driver 102 may determine the rise time is too slow (e.g., greater than a maximum time duration). In such a case, driver 102 may adjust the driving capability of device driver 102 by responsive to determining the rise time is longer than a maximum time duration, increasing the driving capability of device driver 102 from the first level to the second level. For example, if driver 102 determines, based on the indication of rise time, that the rise time is too slow (e.g., longer than seventy-five nano seconds), driver 102 may increase the driving capability of its output stage by causing the biasing current at the output stage to increase from a first current level to a second current level in an effort to reduce the rise time during a subsequent switching cycle.

In some examples, driver 102 may determine the rise time is too fast (e.g., shorter than a minimum time duration). In such an example, driver 102 may adjust the driving capability of device driver 102 by, responsive to determining the rise time is not longer than a maximum time duration and the rise time is shorter than a minimum time duration, decreasing the driving capability of the device driver from the first level to the second level. For example, if driver 102 determines, based on the indication of rise time, that the rise time is too fast (e.g., shorter than thirty nano seconds), driver 102 may decrease the driving capability of its output stage by causing the biasing current at the output stage to decrease from a first current level to a second current level in an effort to increase the rise time during a subsequent switching cycle.

In some examples, driver 102 may determine the rise time is not too fast or too slow. In this case, driver 102 may adjust the driving capability of device driver 102 by not making any adjustment at all. That is, responsive to determining the rise time is not longer than a maximum time duration and the rise time is not shorter than a minimum time duration, driver 102 may maintain the driving capability of the device driver at the first level. For example, if driver 102 determines, based on the indication of rise time, that the rise time is not too slow (e.g., shorter than seventy-five nano seconds) and the rise time is not too fast (e.g., longer than thirty nano seconds), driver 102 may infer that the driving capability of its output stage is adequate for a current load and causing the biasing current at the output stage to stay at its current level without increasing or decreasing the driving capability of driver 102.

In any case, after adjusting the driving capability, driver 102 may output, at the second level of driving capability, the gate driver output during the subsequent switching cycle of semiconductor device 104 (230). For example, driver 102 may generate a subsequent signal at link 106 to again switch-on device 104, for example, by causing the voltage at gate (G) of device 104 to transition from a low voltage (e.g., ground) to a high voltage (e.g., VCC). Only the subsequent signal will be driven at a second level of driving capability as opposed to the first level of driving capability that driver 102 used to drive the initial gate driver output.

Driver 102 may repeat operations 210-230 so as to monitor and adjust the driving capability of the gate driver output until the gate driver output settles on a rise time that is acceptable for the inferred size of the load at link 106. For example, following operation 230 above, driver 102 may repeat operation 210 by determining a subsequent rise time of the gate driver output, based on a subsequent indication of rise time obtained by driver 102, during the subsequent switching cycle of the semiconductor device (210). Then, prior to a third switching cycle of the semiconductor device, driver 102 may perform operation (220) by adjusting, based on the indication of the subsequent rise time, the driving capability of the device driver from the second level to a third level. Lastly, driver 102 may output, at the third level of driving capability, the gate driver output during the third switching cycle of the semiconductor device (230).

In some examples, in response determining that the rise time falls between the maximum time duration and minimum time duration or between two predefined time durations, driver 102 may maintain the driving capability of device driver 102 for one or more switching cycles, before repeating operations 210-230. In other words, rather than continuously check the rise time of the driver gate output after the rise time has settled to an acceptable duration, driver 102 may save electrical power and delay or otherwise wait for a period of time before evaluating again.

For instance, the “subsequent switching cycle” referred to above may include one or more switching cycles so when driver 102 outputs, at the second level of driving capability, the gate driver output during “the subsequent switching cycle” of semiconductor device 104 (230), driver 102 may output the gate driver output at the second level for the one or more switching cycles. In such a case, after maintaining the driving capability of device driver 102 at the second level for the one or more switching cycles, device driver 102 may repeat operations 210-230. Driver 102 may obtain an indication of a subsequent rise time of the gate driver output during a final switching cycle of the one or more switching cycles (210). Then, prior to a third switching cycle occurring after the final switching cycle of the one or more switching cycles, driver 102 may adjust, based on the indication of the subsequent rise time, the driving capability of the device driver from the second level to a third level (220). Driver 102 may finally output, at the third level of driving capability, the gate driver output during the third switching cycle of semiconductor device 104 (230).

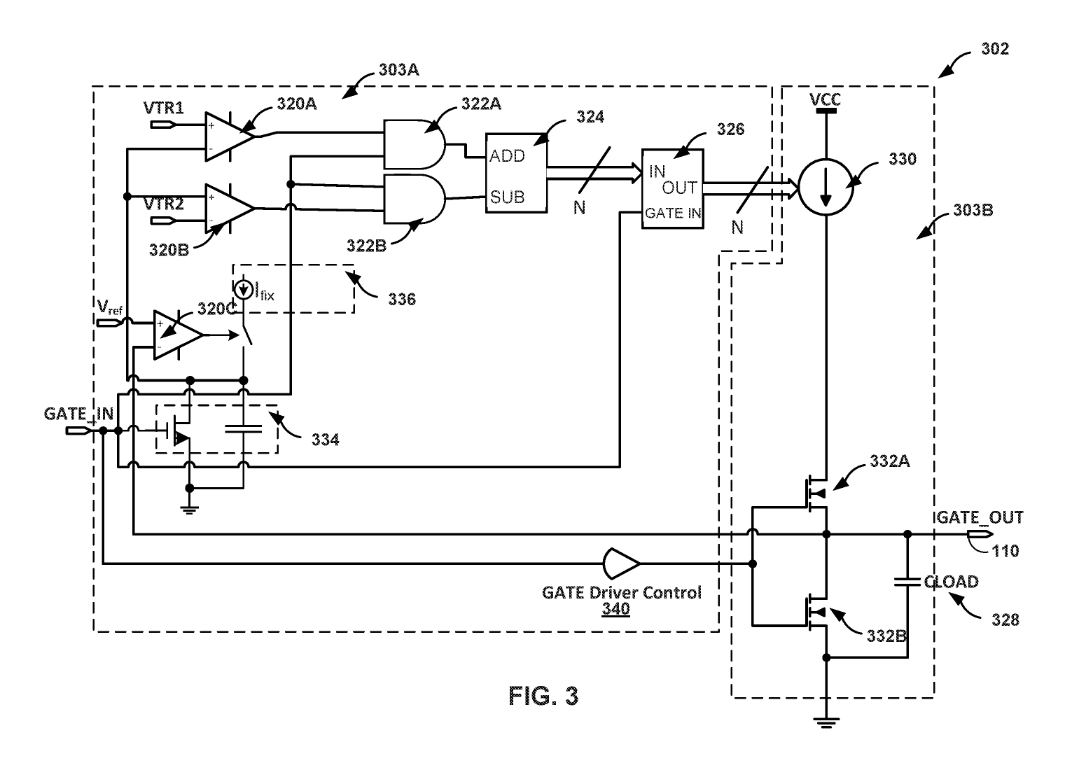

FIG. 3 is a block diagram illustrating an example semiconductor device driver having dynamic drive capability for driving a semiconductor device, in accordance with one or more aspects of the present disclosure. FIG. 3 shows driver 302. Driver 302 is an example of driver 102 of FIG. 1. FIG. 3 is described in the context of FIGS. 1 and 2. Driver 302 includes control components 303A and output stage 303B.

Output stage 303B is configured to produce a gate driver output for driving a gate terminal of a semiconductor device, such as device 104 of FIG. 1. Output stage 303B includes a variable driving capability. As shown in FIG. 3, in some examples, output stage 303B includes current source 330 which acts as a variable current biasing component and control components 303A are configured to adjust the driving capability of driver 302 by changing an amount of current associated with variable current biasing component. In other examples, output stage 303B includes a variable impedance component and control components 303A are configured to adjust the driving capability of driver 302 by changing an amount of impedance associated with the variable impedance component.

Output stage 303B also includes high-side switch e.g., transistor) 332A and low-side switch (e.g., transistor) 332B coupled to output capacitor 328 at the gate output terminal “GATE_OUT”. The gate output terminal of driver 302 may be coupled to link 110 and the gate of a semiconductor device, such as device 104.

Control components 303A of driver 302 include comparators 320A, 320B, and 320C, logic AND gates 322A and 322B, counter 324, and register 326. Control components 303A further include gate driver control component 340, capacitor 334 (in parallel to a transistor switch) and fixed current source 336 (I_{fix}). Control components 303A are configured to receive an input (e.g., from a processor or other external component or device) at the gate input terminal GATE_IN from which control components 303A may infer the phase of a switching cycle (e.g., switch-on phase or switch-off phase).

Control components 303A are configured to obtain an indication of a rise time of the gate driver output at Gate_OUT during an initial switching cycle of a semiconductor device by evaluating a voltage level at capacitor 334 after first charging capacitor 334 with fixed current source 336 from a start time of the initial switching cycle until the gate driver output reaches a maximum voltage level during the initial switching cycle. For example, the negative input of comparator 320C is coupled to the gate output terminal of driver 302. During a switching cycle, gate driver control 340 may receive an input from gate terminal input GATE_IN and in response, cause low-side switch 332B to switch open and high-side switch 332A to switch closed to cause the voltage at the gate output terminal of driver 302 to increase from ground to VCC (e.g., a maximum voltage). While the voltage is increasing at the gate output terminal of driver 302, gate driver control 340 may configure capacitor 334 to be in charging mode (e.g., by preventing a short across capacitor 334). The increasing voltage of the gate output terminal of driver 302 may feed into the input of comparator 320C and cause comparator 320C to produce an output that causes fixed current source 336 to charge capacitor 334 (that is currently in charging mode). The charging of capacitor 334 may produce a voltage across capacitor 334 that is received by comparators 320A and 320B. When the gate voltage reaches the target voltage, gate driver 340 may cause the charging of capacitor 334 to stop. The voltage at capacitor 334 may then be sensed as an indication of rise time of the gate driver output.

Control components 303A are further configured to, prior to a subsequent switching cycle of a semiconductor device, adjust, based on the indication of rise time, a driving capability of device driver 302 from a first level to a second level. Comparators 320A and 320B may produce an output received by AND gates 322A and 322B that varies depending on whether the voltage across capacitor 334 satisfies thresholds VTAR1 or VTAR2. VTAR1 and VTAR2 are internal voltage references. VTAR2 corresponds to the voltage that should appear across capacitor 334 if the rise time is longer than the maximum time duration TAR2. VTAR1 corresponds to the voltage that should appear across capacitor 334 if the rise time is shorter than the minimum time duration TAR1.

For example, if the voltage at capacitor 334 is higher than a voltage threshold VTAR2, it implies that the rise time is longer than a maximum time duration TAR2 and therefore likely too slow, and the current capability will be increased for the next switching cycle. However, if the voltage is lower than a voltage threshold VTAR1, it implies that the rise time is shorter than a minimum time duration TAR1 and therefore likely too fast, and the current capability will be decreased for the next switching cycle. A hysteresis may be maintained to ensure stable operation. Control components 303A are further configured to cause output stage 303B to output the gate driver output at the second level of driving capability during the subsequent switching cycle of the semiconductor device.

In some examples, after the decision to increase the driving capability or decrease the driving capability is made, counter 324 may be used to record number of sensed gate pulses by incrementing. Once counter 324 reaches N count (e.g., the count may be dependent on number of current capability steps designed), driver current capability data may be stored in register 326. After which, there may be no further sensing or adjustment of driver current capability.

To summarize one example of FIG. 3, the voltage of the gate driver output of driver 302 may be charged from 0V (e.g., GNU) to a maximum voltage, while at the same time, current I_{fix} may be used to charge internal capacitor 334. When the voltage of the gate driver output reaches the maximum voltage, I_{fix} may be prevented from further charging internal capacitor 334 so the voltage across internal capacitor 334 acts as an indication of rise time of the gate driver output. If the voltage over capacitor 334 is lower than VTAR1, this may indicate the rise time of the gate driver output is too fast or shorter than a minimum time duration TAR1. In this case, the gate driver capability of driver 302 may be decreased for the next gate driver pulse. Alternatively, if the voltage over capacitor 334 is higher than VTAR2, this may indicate that the rise time of the gate driver output is too slow or longer than a maximum time duration TAR2. In this alternative case, the gate driver capability of driver 302 may be increased for the next gate driver pulse. If the voltage over capacitor 334 is between VTAR1 and VTAR2, this may indicate the rise time of the gate driver output is not too slow and not too fast. When the rise time of the gate driver output is not too slow and not too fast, the gate driver capability of driver 302 may not be modified and may be maintained at its current level for the next gate driver pulse.

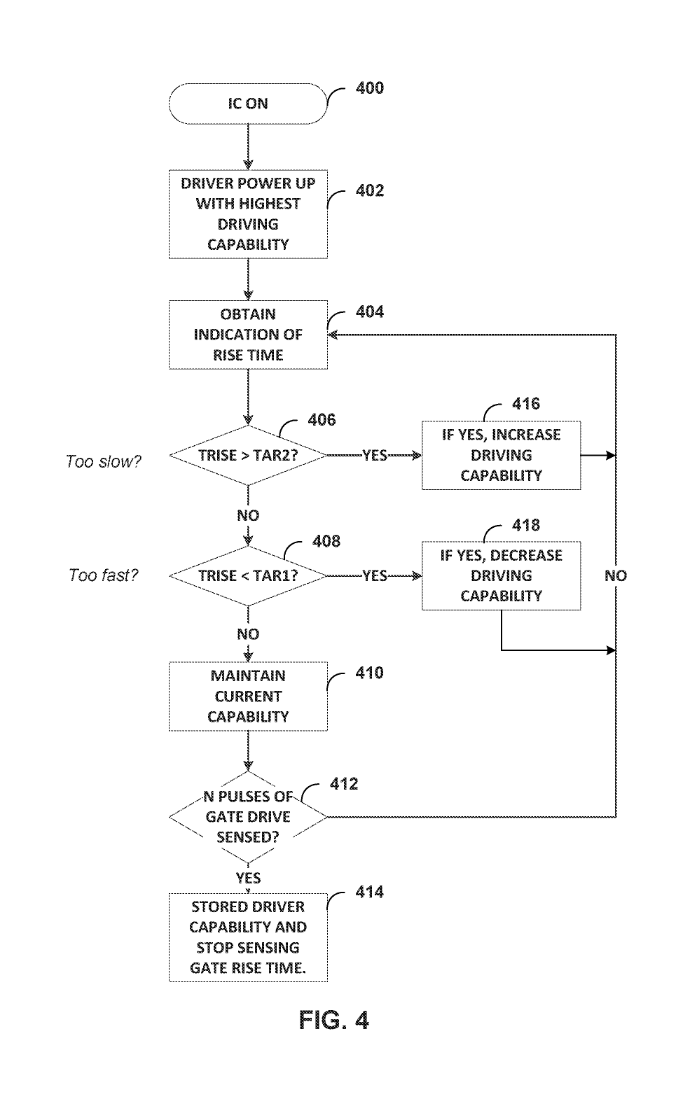

FIG. 4 is a flow diagram illustrating operations performed by the example semiconductor device driver shown in FIG. 3. Operations 400-414 may be performed by control components 303A of FIG. 3. FIG. 4 is described below in the context of FIG. 3.

In operation, driver 302 may power on (400). Initially, control components 303A may cause driver 302 to output a gate driver output using the highest available driving capability (402). For example, current source 303 may be set to a maximum current biasing setting.

Control components 303A may obtain an indication of the rise time of the gate driver output (404). Control components 303A may obtain the indication of the rise time of the gate driver output by sensing a voltage over capacitor 334. That is, control components 303A may charge capacitor 334 with a fixed current 336 from a start time of the initial switching cycle until the gate driver output reaches a maximum voltage level during the initial switching cycle. After charging capacitor 334, control components 303A may inter the rise time based on a voltage level at capacitor 334. Based on the voltage level at capacitor 334, control components 303A may determine whether or not the rise time associated with the gate driver output is too slow or too fast.

Control components 303A may compare the rise time TRISE to a maximum time duration TAR2 by comparing the voltage over capacitor 334 to a voltage threshold VTAR2 (406). The voltage threshold VTAR2 corresponds to the voltage over capacitor 334 if the rise time is longer than a maximum time duration TAR2. If the voltage over capacitor 334 exceeds the voltage threshold VTAR2, control components 303A may infer that the rise time is longer than the maximum time duration TAR2, and may increase the driving capability of driver 302 (416) as this may be an indication that the rise time is too slow. Control components 303A may return to operation (404).

Control components 303A may compare the rise time TRISE to a minimum time duration TAR1 by comparing the voltage over capacitor 334 to a voltage threshold VTAR1 (408). The voltage threshold VTAR1 corresponds to the voltage over capacitor 334 if the rise time is shorter than a minimum time duration TAR1. If the voltage over capacitor 334 is lower than the voltage threshold. VTAR1, control components 303A may infer that the rise time is shorter than the minimum time duration TAR1, and may decrease the driving capability of driver 302 (418) as this may be an indication that the rise time is too fast. Control components 303A may return to operation (404).

Control components 303A may maintain the current driving capability of driver 302 (410). For example, if the voltage over capacitor 334 is between the voltage thresholds VTAR1 and VTAR2, indicating that the rise time is not longer than the maximum time duration TAR2 and not shorter than the minimum time duration TAR1, control components 303A may maintain the driving capability of driver 302 at its current capability as this may be an indication that the rise time is adequate (e.g., not likely to cause radiated EMI or switching losses) for the current load condition at the gate output terminal of driver 302.

Control components 303A may repeat some or all of operations 404, 406, 408, 410, 416, and 418 until N pulses of gate driver output are sensed (412). After sensing N pulses, control components 303A may store the driver capability and stop sensing the gate rise time since driver 302 has now self-calibrated its driving capability to match the current load.

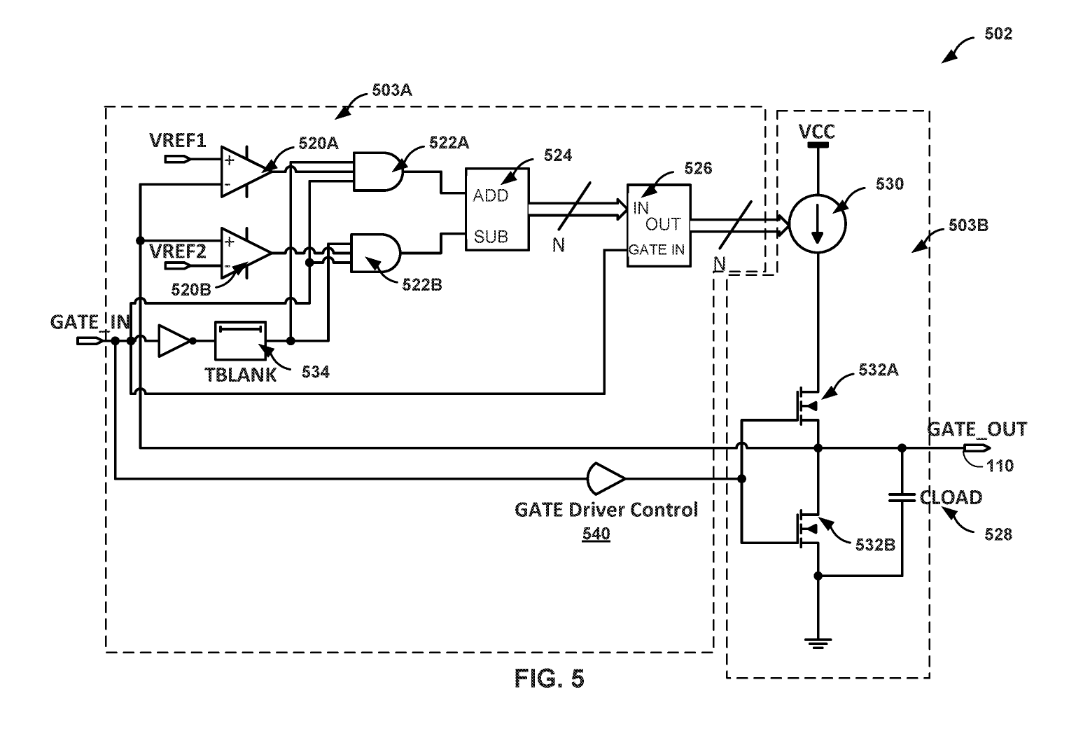

FIG. 5 is a block diagram illustrating another example semiconductor device driver having dynamic drive capability for driving a semiconductor device, in accordance with one or more aspects of the present disclosure. FIG. 5 shows driver 502. Driver 502 is an example of driver 102 of FIG. 1. FIG. 5 is described in the context of FIGS. 1 and 2. Driver 502 includes control components 503A and output stage 503B.

Output stage 503B is configured to produce a gate driver output for driving a gate terminal of a semiconductor device, such as device 104 of FIG. 1. Output stage 503B includes a variable driving capability. As shown in FIG. 5, in some examples, output stage 503B includes current source 530 which acts as a variable current biasing component and control components 503A are configured to adjust the driving capability of driver 502 by changing an amount of current associated with variable current biasing component. In other examples, output stage 503B includes a variable impedance component and control components 503A are configured to adjust the driving capability of driver 502 by changing an amount of impedance associated with the variable impedance component.

Output stage 503B also includes high-side switch (e.g., transistor) 532A and low-side switch (e.g., transistor) 532B coupled to output capacitor 528 at the gate output terminal “GATE_OUT”. The gate output terminal of driver 502 may be coupled to link 110 and the gate of a semiconductor device, such as device 104.

Control components 503A of driver 502 include comparators 520A and 520B, logic AND gates 522A and 522B, counter 524, and register 526. Control components 503A further include gate driver control component 540, and blanking unit 534 which is configured to delay its output for a period of TBLANK time. Control components 503A are configured to receive an input (e.g., from a processor or other external component or device) at the gate input terminal GATE_IN from which control components 503A may infer the phase of a switching cycle (e.g., switch-on phase or switch-off phase).

TBLANK can be set to a predefined number based on different applications. In some embodiments, TBLANK can be set to a number within an acceptable rise time range [t1, t2], wherein the rise time range corresponds to an expected or anticipated range of load. For example, if the device is expected to work in an application with an expected load or load range, the expected rise time or rise time range can be calculated in advance. Then the TBLANK can be set to the rise time or a number within the rise time range, so that the measured voltage at the gate driver output can be used to compare with the predefined reference voltages, e.g., VREF1 and VREF2.

Control components 503A are configured to obtain an indication of a rise time of the gate driver output at Gate_OUT during an initial switching cycle of a semiconductor device by evaluating a voltage level of the gate driver output after a fixed amount of time (TBLANK) since a start time of the initial switching cycle. Control components 503A may measure the voltage level of the gate driver output directly from terminal GATE_OUT. For example, one of the inputs of each of comparators 520A and 520B are coupled to the gate output terminal of driver 502, which, when compared to VREF1 and VREF2 and fully evaluated by control components 503A, provides control components 503A with an indication of the rise time.

During a switching cycle, gate driver control 540 may receive an input from gate terminal input GATE_IN and in response, cause low-side switch 532B to switch open and high-side switch 532A to switch closed to cause the voltage at the gate output terminal of driver 502 to increase from ground to VCC (e.g., a maximum or predefined voltage). Since the input signal at the gate input terminal GATE_IN is delayed by blanking unit 534, the voltage level of the gate driver output does not actually get evaluated by control components 503A until the fixed amount of time (TBLANK) has passed. That is, while the voltage is increasing at the gate output terminal of driver 502, the input to gate driver control 540, at GATE_IN, may be delayed by blanking unit 534 from reaching logic. AND gates 522A and 522B until the fixed amount of time (TBLANK) has passed, thereby preventing the outputs from comparators 520A and 520B from being evaluated for inferring rise time.

Control components 503A are further configured to, prior to a subsequent switching cycle of a semiconductor device, adjust, based on the indication of the rise time, a driving capability of device driver 502 from a first level to a second level. For example, comparators 520A and 520B may produce an output received by AND gates 522A and 522B that varies depending on the voltage at the gate driver output, and is evaluated by AND gates 522A and 522B after TBLANK has passed. If the output from comparator 520A indicates that the gate voltage is lower than VREF1 after TBLANK has passed, it implies that the rise time is too slow (e.g., longer than a maximum time duration) and the current capability will be increased for the next switching cycle. If the output from comparator 520B indicates that the gate voltage is higher than VREF2 after TBLANK has passed, it implies that the rise time is too fast (e.g., shorter than a minimum time duration) and the current capability will be decreased for the next switching cycle. A hysteresis may be maintained to ensure stable operation. Control components 502A are further configured to cause output stage 503B to output the gate driver output at the second level of driving capability during the subsequent switching cycle of the semiconductor device.

In some examples, after the decision to increase the driving capability or decrease the driving capability is made, counter 524 may be used to record number of sensed gate pulses by incrementing. Once counter 524 reaches N count (e.g., the count may be dependent on number of current capability steps designed), driver current capability data may be stored in register 526. After which, there may be no further sensing or adjustment of driver current capability.

To summarize one example of FIG. 5, the voltage of the gate driver output may be charged from 0V to a maximum or predefined voltage, while at the same time, one fixed blanking time may be inserted, and after this blanking time, the measured voltage of the gate driver output may be evaluated. When the voltage of the gate driver output of driver 502 is lower than VREF1, indicating that rise time of the gate driver output is too slow, the driver capability of driver 502 may be increased for the next gate driver pulse; when the voltage of the gate driver output of driver 502 is higher than VREF2, indicating that rise time of the gate driver output is too fast, the driver capability of driver 502 may be decreased for the next gate driver pulse. When the voltage of the gate driver output of driver 502 is between VREF1 and VREF2, the gate driver capability of driver 502 may not be modified and may be maintained at its current level for the next gate driver pulse.

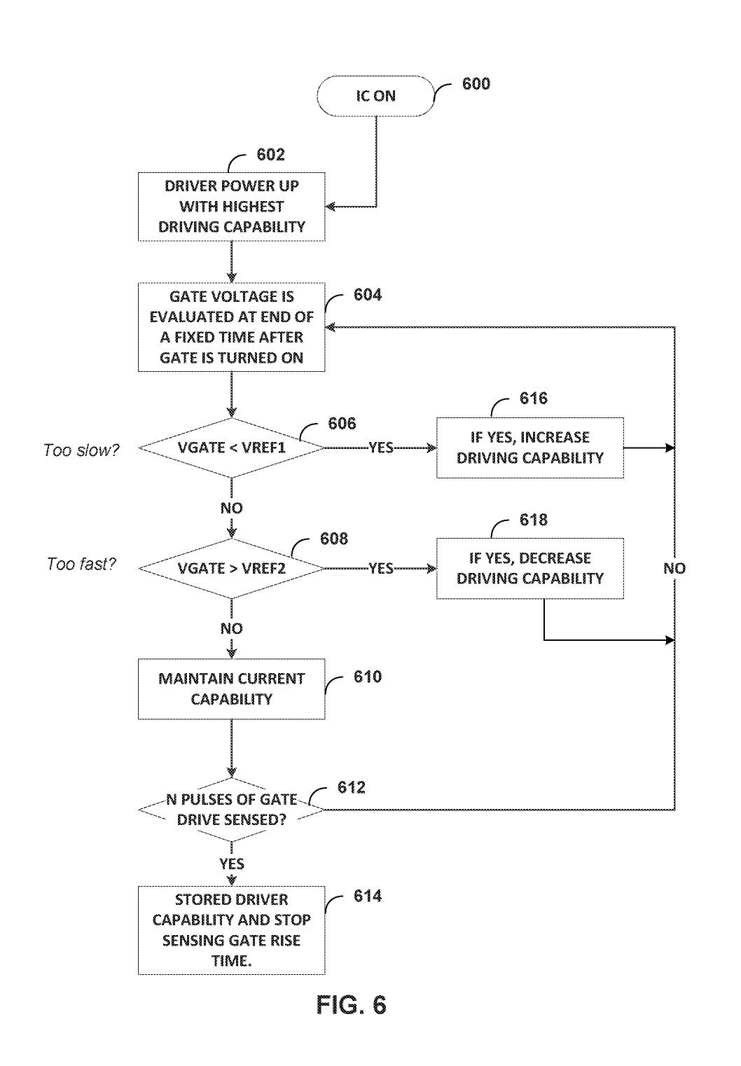

FIG. 6 is a flow diagram illustrating operations performed by the example semiconductor device driver shown in FIG. 5. Operations 600-614 may be performed by control components 502A of FIG. 5. FIG. 6 is described below in the context of FIG. 5.

In operation, driver 502 may power on (600). Initially, control components 503A may cause driver 502 to output a gate driver output using the highest available driving capability (602). For example, current source 503 may be set to a maximum current biasing setting.

Control components 503A may next obtain an indication of the rise time of the gate driver output (604) based on a measured voltage level of the gate driver output when evaluated at a fixed amount of time (e.g., TBLANK) since a start time of the initial switching cycle. Control components 503A may determine whether or not the voltage at the gate driver output, after a fixed amount of time, indicates that the rise time of the gate driver output may be too slow or too fast, which in some instances may contribute to EMI radiation or switching losses.

Control components 503A may compare the voltage at the gate driver output to a first threshold (VREF1) (606). If the voltage at the gate driver output is lower than the first threshold VREF1, control components 503A may increase the driving capability of driver 502 (616) as this may be an indication that the rise time is too slow (e.g., longer than a maximum time duration). Control components 503A may repeat operation (604).

If the voltage at the gate driver output is not lower than the first threshold VREF1, control components 503A may compare the voltage at the gate driver output to a second threshold (VREF2) (608). If the voltage at the gate driver output is higher than the second threshold VREF2, control components 503A may decrease the driving capability of driver 502 (618) as this may be an indication that the rise time is too fast (e.g., shorter than a minimum time duration). Control components 503A may repeat operation (604).

If, however, the voltage at the gate driver output is not higher than the second threshold VREF2 and not lower than the first threshold VREF1, control components 503A may maintain the current driving capability of driver 502 (610) (e.g., without adjustment) as this may be an indication that the rise time is about right for the current load condition at the gate output terminal of driver 502.

Control components 503A may repeat some or all of operations 604, 606, 608, 610, 616, and 618 until N pulses of gate driver output are sensed (612). After sensing N pulses, control components 503A may store the driver capability and stop sensing the gate rise time since driver 502 has now self-calibrated its driving capability to match the current load.

The following “clauses” demonstrate some specific aspects of devices and techniques according to this disclosure.

Clause 1. A device driver comprising: an output stage configured to produce a gate driver output for driving a gate terminal of a semiconductor device, the output stage comprising a variable driving capability; and one or more control components configured to: obtain an indication of a rise time of the gate driver output during an initial switching cycle of the semiconductor device; prior to a subsequent switching cycle of the semiconductor device, adjust, based on the indication of the rise time, a driving capability of the device driver from a first level to a second level; and cause the output stage to output the gate driver output at the second level of driving capability during the subsequent switching cycle of the semiconductor device.

Clause 2. The device driver of clause 1, wherein the one or more control components comprise a capacitor and a fixed current source, and the one or more control components are further configured to obtain the indication of the rise time of the gate driver by at least evaluating a voltage level at the capacitor after charging the capacitor with the fixed current source from a start time of the initial switching cycle until the gate driver output reaches a maximum or predefined voltage level during the initial switching cycle.

Clause 3. The device driver of any of clauses 1-2, wherein the one or more control components are further configured to obtain the indication of the rise time of the gate driver by at least evaluating a voltage level of the gate driver output at a fixed amount of time since a start time of the initial switching cycle.

Clause 4. The device driver of any of clauses 1-3, wherein the one or more control components are further configured to adjust the driving capability of the device driver by at least: responsive to determining the indication of the rise time indicates that the rise time is longer than a maximum time duration, increase the driving capability of the device driver from the first level to the second level; and responsive to determining the indication of the rise time indicates that the rise time is not longer than the maximum time duration and the rise time is shorter than a minimum time duration, decreasing the driving capability of the device driver from the first level to the second level.

Clause 5. The device driver of any of clauses 1-4, wherein the one or more control components are further configured to adjust the driving capability of the device driver by at least responsive to determining the indication of the rise time indicates that the rise time is not longer than a maximum time duration and the indication of the rise time indicates that the rise time is not shorter than a minimum time duration, maintain the driving capability of the device driver at the first level.

Clause 6. The device driver of any of clauses 1-5, wherein the semiconductor device comprises a power metal-oxide-semiconductor field-effect-transistor device.

Clause 7. The device driver of any of clauses 1-6, wherein the device driver comprises at least a portion of a controller configured to modulate the semiconductor device with the gate driver output.

Clause 8. The device driver of any of clauses 1-7, wherein the driving capability of the output stage comprises a variable impedance component and the one or more control components are configured to adjust the driving capability by changing an amount of impedance associated with the variable impedance component.

Clause 9. The device driver of any of clauses 1-8, wherein the driving capability of the output stage comprises a variable current biasing component and the one or more control components are configured to adjust the driving capability by changing an amount of current associated with the variable current biasing component.

Clause 10. A system comprising: means for obtaining an indication of a rise time of a gate driver output during an initial switching cycle of a semiconductor device; prior to a subsequent switching cycle of the semiconductor device, means for adjusting, based on the indication of the rise time, a driving capability of the system from a first level to a second level; and means for outputting at the second level of driving capability, the gate driver output during the subsequent switching cycle of the semiconductor device.

Clause 11. A method comprising: obtaining, by a device driver, art indication of a rise time of a gate driver output during an initial switching cycle of a semiconductor device; prior to a subsequent switching cycle of the semiconductor device, adjusting, by the device driver, based on the indication of the rise time, a driving capability of the device driver from a first level to a second level; and outputting, by the device driver, at the second level of driving capability, the gate driver output during the subsequent switching cycle of the semiconductor device.

Clause 12. The method of clause 11, wherein adjusting the driving capability of the device driver comprises responsive to determining the indication of the rise time indicates the rise time is longer than a maximum time duration, increasing, by the device driver, the driving capability of the device driver from the first level to the second level.

Clause 13. The method of any of clauses 11-12, wherein adjusting the driving capability of the device driver further comprises responsive to determining the indication of the rise time indicates the rise time is not longer than a maximum time duration and the rise time is shorter than a minimum time duration, decreasing by the device driver, the driving capability of the device driver from the first level to the second level.

Clause 14. The method of any of clauses 11-13, wherein adjusting the driving capability of the device driver further comprises responsive to determining the indication of the rise time indicates the rise time is not longer than a maximum time duration and the rise time is not shorter than a minimum time duration, maintaining, by the device driver, the driving capability of the device driver at the first level.

Clause 15. The method of clause 14, wherein: the indication of the rise time is an initial indication of an initial rise time, the subsequent switching cycle comprises one or more switching cycles of the semiconductor device; and the method further comprises: after maintaining the driving capability of the device driver at the first level for the one or more switching cycles, obtaining, by the device driver, a subsequent indication of a subsequent rise time of the gate driver output during a final switching cycle of the one or more switching cycles; prior to a third switching cycle occurring after the final switching cycle of the one or more switching cycles, adjusting, by the device driver, based on the subsequent indication of the subsequent rise time, the driving capability of the device driver from the second level to a third level; and outputting, by the device driver, at the third level of driving capability, the gate driver output during the third switching cycle of the semiconductor device.

Clause 16. The method of any of clauses 11-15, wherein the indication of the rise time is an initial indication of an initial rise time, the method further comprising:

obtaining, by the device driver, a subsequent indication of a subsequent rise time of the gate driver output during the subsequent switching cycle of the semiconductor device; prior to a third switching cycle of the semiconductor device, adjusting, by the device driver, based on the subsequent indication of the subsequent rise time, the driving capability of the device driver from the second level to a third level; and outputting, by the device driver, at the third level of driving capability, the gate driver output during the third switching cycle of the semiconductor device.

Clause 17. The method of any of clauses 11-16, wherein adjusting the driving capability comprises changing, by the device driver, an amount of impedance at an output stage of the device driver.

Clause 18. The method of any of clauses 11-17, wherein adjusting the driving capability comprises changing, by the device driver, an amount of current biasing at an output stage of the device driver.

Clause 19. The method of any of clauses 11-18, wherein obtaining the rise time of the gate driver output comprises: charging, by the driver device, a capacitor with a fixed current from a start time of the initial switching cycle until the gate driver output reaches a maximum or predefined voltage level during the initial switching cycle; and after charging the capacitor, evaluating, by the driver device, a voltage level at the capacitor.

Clause 20. The method of any of clauses 11-19, wherein obtaining the indication of the rise time of the gate driver output comprises evaluating, by the driver device, a voltage level of the gate driver output that is measured at a fixed amount of time since a start time of the initial switching cycle.

Clause 21. A system comprising means for performing any of the methods of clauses 11-20.

Clause 22. A computer-readable storage medium comprising instructions, that when executed by at least one processor, cause the at least one processor to perform any of the methods of clauses 11-20.

Clause 23. A controller comprising one or more components configured to perform any of the methods of clauses 11-20.

In one or more examples, the driver functions being performed described may be implemented in hardware, software, firmware, or any combination thereof. If implemented in software, the functions may be stored on or transmitted over, as one or more instructions or code, a computer-readable medium and executed by a hardware-based processing unit. Computer-readable media may include computer-readable storage media, which corresponds to a tangible medium such as data storage media, or communication media including any medium that facilitates transfer of a computer program from one place to another, e.g., according to a communication protocol. In this manner, computer-readable media generally may correspond to (1) tangible computer-readable storage media, which is non-transitory or (2) a communication medium such as a signal or carrier wave. Data storage media may be any available media that can be accessed by one or more computers or one or more processors to retrieve instructions, code and/or data structures for implementation of the techniques described in this disclosure. A computer program product may include a computer-readable medium.

The techniques of this disclosure may be implemented in a wide variety of devices or apparatuses, including a wireless handset, an integrated circuit (IC) or a set of ICs (e.g., a chip set). Various components, modules, or units are described in this disclosure to emphasize functional aspects of devices configured to perform the disclosed techniques, but do not necessarily require realization by different hardware units. Rather, as described above, various units may be combined in a hardware unit or provided by a collection of interoperative hardware units, including one or more processors as described above, in conjunction with suitable software and/or firmware.

Various examples have been described. These and other examples are within the scope of the following claims.

1. A device driver comprising:
an output stage configured to produce a gate driver output for driving a gate terminal of a semiconductor device, wherein the semiconductor device comprises a power metal-oxide-semiconductor field-effect-transistor device of a switched-mode power supply; and
one or more control components configured to:
at power-on of the device driver and during an initial switching cycle of the semiconductor device, cause the output stage to produce the gate driver output at a maximum driving capability of the device driver;
obtain an indication of a rise time of the gate driver output during the initial switching cycle by evaluating a voltage level at a capacitor of the output stage after charging the capacitor with a fixed current source of the output stage from a start time until an end time at which the gate driver output is at the maximum driving capability of the device driver;
cause the charging the capacitor with the fixed current source to cease at the end time at which the gate driver output is at the maximum driving capability of the device driver;
prior to a subsequent switching cycle of the semiconductor device, adjust, based on the indication of the rise time, a driving capability of the device driver from a first level that corresponds to the maximum driving capability to a second level; and
cause the output stage to output the gate driver output at the second level of driving capability during the subsequent switching cycle.

2. (canceled)

3. The device driver of claim 1, wherein the one or more control components are further configured to obtain the indication of the rise time of the gate driver by at least evaluating a voltage level of the gate driver output when measured at a fixed amount of time since a start time of the initial switching cycle.

4. The device driver of claim 1, wherein the one or more control components are further configured to adjust the driving capability of the device driver by at least:
responsive to determining the indication of the rise time indicates that the rise time is longer than a maximum time duration, increasing the driving capability of the device driver from the first level to the second level; and
responsive to determining the indication of the rise time indicates that the rise time is not longer than the maximum time duration and the rise time is shorter than a minimum time duration, decreasing the driving capability of the device driver from the first level to the second level.

5. The device driver of claim 1, wherein the one or more control components are further configured to adjust the driving capability of the device driver by at least responsive to determining the indication of the rise time indicates that the rise time is not longer than a maximum time duration and the rise time is not shorter than a minimum time duration, maintain the driving capability of the device driver at the first level.

6. (canceled)

7. The device driver of claim 1, wherein the device driver comprises at least a portion of a controller configured to modulate the semiconductor device with the gate driver output.

8. The device driver of claim 1, wherein the output stage comprises a variable impedance component and the one or more control components are configured to adjust the driving capability by changing an amount of impedance associated with the variable impedance component.

9. The device driver of claim 1, wherein the output stage comprises a variable current biasing component and the one or more control components are configured to adjust the driving capability by changing an amount of current associated with the variable current biasing component.

10. A system comprising:
means for producing, at power-on of the system and during an initial switching cycle of a semiconductor device, a gate driver output, for driving a gate terminal of the semiconductor device at a maximum driving capability of the system;
means for obtaining an indication of a rise time of the gate driver output during the initial switching cycle by evaluating a voltage level at a capacitor after charging the capacitor with a fixed current source from a start time until an end time at which the gate driver output is at the maximum driving capability of the system;
means for causing the charging the capacitor with the fixed current source to cease at the end time at which the gate driver output is at the maximum driving capability of the system;
means for adjusting, prior to a subsequent switching cycle of the semiconductor device and based on the indication of the rise time, a driving capability of the system from a first level that corresponds to the maximum driving capability to a second level; and
means for outputting at the second level of driving capability, the gate driver output during the subsequent switching cycle.

11. A method comprising:
by a device driver that comprises a capacitor, a fixed current source and an output stage configured to produce a gate driver output for driving a gate terminal of a semiconductor device of a switched-mode power supply:
causing, at power-on of the device driver, the output stage to produce the gate driver output at a maximum driving capability of the device driver and during an initial switching cycle of the semiconductor device;
obtaining an indication of a rise time of the gate driver output during the initial switching cycle of the semiconductor device by evaluating a voltage level at the capacitor after charging the capacitor with the fixed current source from a start time until an end time at which the gate driver output is at the maximum driving capability of the device driver;
causing the charging the capacitor with the fixed current source to cease at the end time at which the gate driver output is at the maximum driving capability of the device driver;
prior to a subsequent switching cycle of the semiconductor device, adjusting a driving capability of the device driver from a first level that corresponds to the maximum driving capability to a second level based on the indication of the rise time; and
outputting, by the device driver, at the second level of driving capability, the gate driver output during the subsequent switching cycle.

12. The method of claim 11, wherein adjusting the driving capability of the device driver comprises responsive to determining the indication of the rise time indicates that the rise time is longer than a maximum time duration, increasing, by the device driver, the driving capability of the device driver from the first level to the second level.

13. The method of claim 11, wherein adjusting the driving capability of the device driver further comprises responsive to determining the indication of the rise time indicates that the rise time is not longer than a maximum time duration and the rise time is shorter than a minimum time duration, decreasing by the device driver, the driving capability of the device driver from the first level to the second level.

14. The method of claim 11, wherein adjusting the driving capability of the device driver further comprises responsive to determining the indication of the rise time indicates that the rise time is not longer than a maximum time duration and the rise time is not shorter than a minimum time duration, maintaining, by the device driver, the driving capability of the device driver at the first level.

15. The method of claim 14, wherein:
the indication of the rise time is an initial indication of an initial rise time,
the subsequent switching cycle comprises one or more switching cycles of the semiconductor device; and
the method further comprises:
after maintaining the driving capability of the device driver at the first level for the one or more switching cycles, obtaining, by the device driver, a subsequent indication of a subsequent rise time of the gate driver output during a final switching cycle of the one or more switching cycles;
prior to a third switching cycle occurring after the final switching cycle of the one or more switching cycles, adjusting, by the device driver, based on the subsequent indication of the subsequent rise time, the driving capability of the device driver from the second level to a third level; and
outputting, by the device driver, at the third level of driving capability, the gate driver output during the third switching cycle of the semiconductor device.

16. The method of claim 11, wherein the indication of the rise time is an initial indication of an initial rise time, the method further comprising:
obtaining, by the device driver, a subsequent indication of a subsequent rise time of the gate driver output during the subsequent switching cycle of the semiconductor device;
prior to a third switching cycle of the semiconductor device, adjusting, by the device driver, based on the subsequent indication of the subsequent rise time, the driving capability of the device driver from the second level to a third level; and
outputting, by the device driver, at the third level of driving capability, the gate driver output during the third switching cycle of the semiconductor device.

17. The method of claim 11, wherein adjusting the driving capability comprises changing, by the device driver, an amount of impedance at an output stage of the device driver.

18. The method of claim 11, wherein adjusting the driving capability comprises changing, by the device driver, an amount of current biasing at an output stage of the device driver.

19. (canceled)

20. The method of claim 11, wherein obtaining the indication of the rise time of the gate driver output comprises evaluating, by the driver device a voltage level of the gate driver output that is measured at a fixed amount of time since a start time of the initial switching cycle.
